(19) United States
(12) Patent Application Publication
(10) Pub. No.: US 2025/0311636 A1
(43) Pub. Date: Oct. 2, 2025

(54) MAGNETOELECTRIC SPIN–ORBIT (MESO) DEVICE WITH UNCONVENTIONAL SPIN-TO-CHARGE CONVERSION

(71) Applicant: Intel Corporation, Santa Clara, CA (US)

(72) Inventors: Mahendra DC, Portland, OR (US); Punyashloka Debashis, Hillsboro, OR (US); Hai Li, Portland, OR (US); Ian Alexander Young, Olympia, WA (US); Marko Radosavljevic, Portland, OR (US); John J. Plombon, Portland, OR (US); Scott B. Clendenning, Portland, OR (US); Carly Rogan, North Plains, OR (US); Jennifer Lux, Hillsboro, OR (US); Christopher M. Gay, Portland, OR (US); Tristan A. Tronic, Aloha, OR (US); Yu-Ching Liao, Portland, OR (US); Karam Cho, Hillsboro, OR (US); Dominique A. Adams, Portland, OR (US)

(73) Assignee: Intel Corporation, Santa Clara, CA (US)

(21) Appl. No.: 18/617,272

(22) Filed: Mar. 26, 2024

(51) Int. Cl. H10N 50/20; H10N 50/01; H10N 50/85

(52) U.S. Cl. CPC H10N 50/20; H10N 50/01; H10N 50/85

(57) ABSTRACT

Magnetoelectric spin-orbit (MESO) devices, integrated circuit devices and systems with MESO devices, and methods of forming the same, are disclosed herein. In one embodiment, a semiconductor device includes: a first layer that includes a conductive material; a second layer over the first layer, where the second layer includes a magnetoelectric material; one or more third layers over the second layer, where the third layer(s) include one or more ferromagnetic materials; and a fourth layer over the third layer(s), wherein the fourth layer includes platinum, cobalt, and oxygen.

### BACKGROUND

Magnetoelectric spin-orbit (MESO) logic is a type of spintronic logic that operates using the magnetoelectric effect in conjunction with the spin-orbit coupling effect (e.g., the coupling of an electron's inherent angular momentum with its translational orbital motion). For example, magnetoelectric switching can be used to convert an input voltage/charge into a magnetic spin state (e.g., charge-to-spin conversion), and spin-orbit transduction can be used to convert the magnetic spin state back into an output charge/voltage (e.g., spin-to-charge conversion). In some cases, however, the output voltage may be relatively low due to inefficiencies in the spin-to-charge conversion, which makes it challenging to cascade MESO devices together to form large-scale integrated circuits.

### BRIEF DESCRIPTION OF THE DRAWINGS

FIGS. 1A-C illustrate an example of a MESO device with conventional and unconventional spin-to-charge conversion.

FIG. 2 illustrates an example of the composition of a spin-orbit coupled layer for a MESO device.

FIGS. 3A-E illustrate an example process flow for forming a MESO device with conventional and unconventional spin-to-charge conversion.

FIG. 4 illustrates an example of cascaded MESO logic.

FIG. 5 illustrates a flowchart for forming integrated circuitry with one or more MESO devices in accordance with certain embodiments.

FIG. 6 is a top view of a wafer and dies that may be included in a microelectronic assembly.

FIG. 7 is a cross-sectional side view of an integrated circuit device that may be included in a microelectronic assembly.

FIG. 8 is a cross-sectional side view of an integrated circuit device assembly that may include a microelectronic assembly.

FIG. 9 is a block diagram of an example electrical device that may include a microelectronic assembly.

### DETAILED DESCRIPTION

Spintronic logic refers to a class of semiconductor devices that leverage the physical properties of magnetization—such as the spin of electrons and their magnetic moments—to represent and manipulate data. As an example, the magnetic spin state of electrons can be used to represent logic states, logic values, bits, compute variables, and so forth.

Magnetoelectric spin-orbit (MESO) logic is a type of spintronic logic that operates using the magnetoelectric effect in conjunction with the spin-orbit coupling effect (e.g., the coupling of an electron's inherent angular momentum with its translational orbital motion). In particular, the magnetoelectric effect is used to control or manipulate the spin state of a magnet, and the spin-orbit coupling effect is used to read out the spin state of the magnet. For example, magnetoelectric switching can be used to convert charge produced by an input voltage into a magnetic spin state (e.g., charge-to-spin conversion), and spin-orbit transduction can be used to convert the magnetic spin state back into charge (e.g., spin-to-charge conversion) to produce an output voltage.

In some embodiments, for example, MESO logic can be used to implement a non-volatile logic device, such as a logic switch/gate with a non-volatile logical state. For example, a MESO logic device can convert a logical state represented by an input voltage/charge into a (non-volatile) magnetic spin state, and then subsequently convert the magnetic spin state back into an output charge/voltage to read out the logical state. Moreover, since the magnetic spin state is non-volatile, the logical state is preserved when power is switched off, which means a MESO logic device is extremely energy efficient.

As a result, MESO logic devices are a super-energy-efficient alternative to complementary metal-oxide-semiconductor (CMOS) logic devices (e.g., CMOS transistors). For example, analogous to CMOS devices, MESO logic devices can be used to implement logic circuitry in scalable integrated circuits. Compared to CMOS technology, however, MESO logic has superior energy efficiency (e.g., lower energy consumption for switching, which translates into lower operating voltage), higher integration density and efficiency (e.g., more logic functions per unit area, fewer devices required per logic function), and non-volatility (e.g., which counteracts leakage power and enables ultralow standby power).

One of the challenges associated with designing MESO logic, however, is ensuring that the output signal of one MESO device is large enough to drive the input of other MESO devices. For example, MESO logic is typically implemented as a collection of cascaded MESO devices, where the output of one MESO device serves as the input to one or more other MESO devices. As a result, the output signal of each MESO device needs to be high enough to drive the input signal to the next MESO device(s). The output power of a MESO device is dependent on the efficiency of the spin-to-charge conversion readout, however, which can be a limiting factor in achieving high output voltage.

For example, to read out the direction of magnetization induced on the magnet, a voltage (V_{DD}) is applied to cause charge current (I_{SUPPLY}) to flow into the magnet, which in turn causes the magnet to produce spin polarized current whose spin polarization aligns with the direction of magnetization in the magnet. The spin polarized current in the magnet is injected into a layer with high spin-orbit coupling (SOC)—referred to as the SOC readout layer—which performs “spin-to-charge conversion” to convert the spin polarized current into charge current. In this manner, the resulting charge current produces an output voltage (+−V_{OUT}) with a polarity corresponding to the direction of magnetization in the magnet, which serves as the output of the MESO device.

In conventional MESO devices, spin-to-charge conversion is typically achieved in the SOC layer via the inverse spin Hall effect (SHE), which may be referred to herein as conventional spin-to-charge conversion. The inverse SHE is a phenomenon where an applied electric field induces charge current perpendicular to both the direction of spin polarization and the flow of spin current in materials with strong spin-orbit coupling (SOC) (e.g., heavy metals such as platinum (Pt), tantalum (Ta), or tungsten (W)). Thus, with conventional spin-to-charge conversion, the direction of magnetization (m) and spin polarization (σ), the flow of spin current (J_{S}), and the flow of charge current (J_{C}) are orthogonal to each other. For example, the direction of magnetization (m) and spin polarization (o) may be aligned along the x axis, spin current (J_{S}) may flow along the z axis, and charge current (J_{C}) may flow along the y axis. In some cases, however, the output voltage may be relatively low due to inefficiencies in conventional spin-to-charge conversion using the inverse SHE.

Accordingly, this disclosure presents embodiments of MESO devices that leverage unconventional spin-to-charge conversion to achieve higher output voltage. In particular, with unconventional spin-to-charge conversion, the flow of charge current (J_{C}) is aligned with the direction of magnetization (m) and spin polarization (o) and perpendicular to the flow of spin current (J_{S}). For example, the direction of magnetization (m) and spin polarization (o) and the flow of charge current (J_{C}) may be aligned along the x axis, and the flow of spin current (J_{S}) may be aligned along the z axis. This spin-to-charge conversion approach is unconventional because the flow of charge current (J_{C}) is aligned with, instead of perpendicular to, the direction of magnetization (m) and spin polarization (o).

In some embodiments, a MESO device may achieve unconventional spin-to-charge conversion using a compositionally-graded spin-orbit coupling (SOC) layer with high SOC and inversion asymmetry. For example, the SOC layer may be made of platinum (Pt), cobalt (Co), and oxygen (O) (e.g., PtCoOₓ). Moreover, the SOC layer may be compositionally graded using a vertical composition gradient, thus breaking inversion symmetry along the z axis, which results in unconventional spin-to-charge conversion in the SOC layer.

The described embodiments may provide various advantages, including enhanced spin-to-charge conversion efficiency and higher output voltage. For example, the SOC layer converts injected spin current from the magnetic layer into charge current more efficiently using unconventional spin-to-charge conversion, which enhances the read output voltage. The output voltage from unconventional spin-to-charge conversion may be significantly larger than that of conventional spin-to-charge conversion. In some cases, for example, the enhanced efficiency of unconventional spin-to-charge conversion may increase the output voltage by a factor of 10 (10×).

Moreover, the output voltage may increase even further as the MESO device is scaled down in size. In particular, the output voltage is proportional to the resistivity of the SOC layer (e.g., higher resistivity=higher output voltage), and the resistivity of PtCoOₓ increases significantly in nanoscale devices, while the resistivity of other SOC materials (e.g., Pt, Ta, W) remains constant. Thus, as the SOC layer is scaled down in size and becomes narrower, the resistivity of the PtCoOₓ material in the SOC layer increases, which results in higher output voltage. In some cases, this may independently increase the output voltage by another factor of 10 (10×).

Further, in some embodiments, conventional and unconventional spin-to-charge conversion can be used together to further enhance the MESO readout voltage (e.g., by adding the differential voltage outputs from the respective spin-to-charge conversion techniques).

The described embodiments are also conducive to large-scale production, as the SOC layer (e.g., PtCoOₓ) can be polycrystalline, which can be grown with high-volume manufacturing (HVM) tools (e.g., using physical vapor deposition (PVD) techniques such as magnetron sputtering), and no epitaxy is required for the growth.

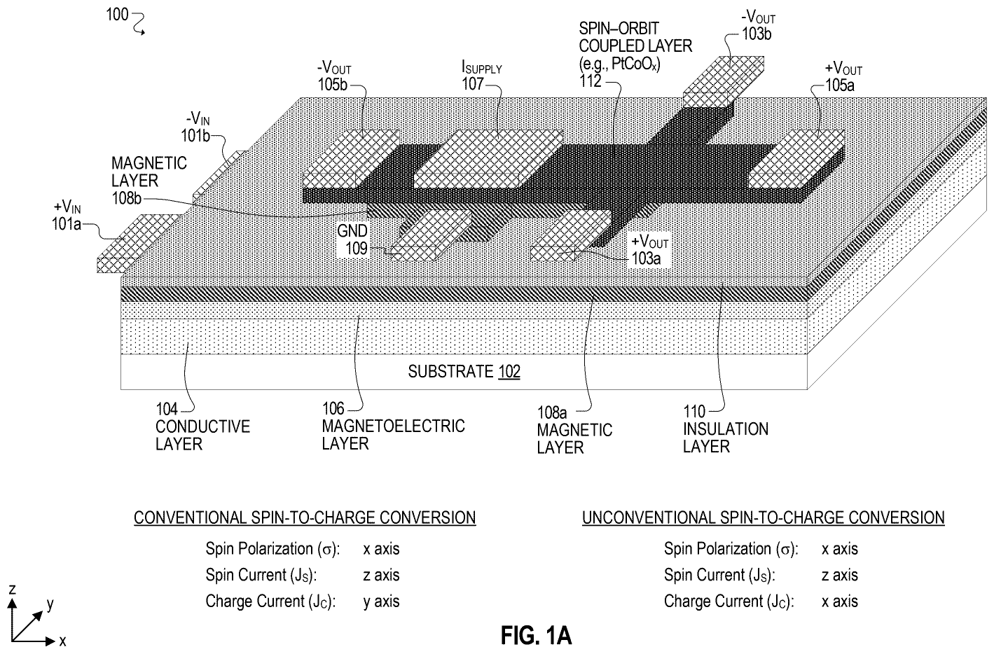

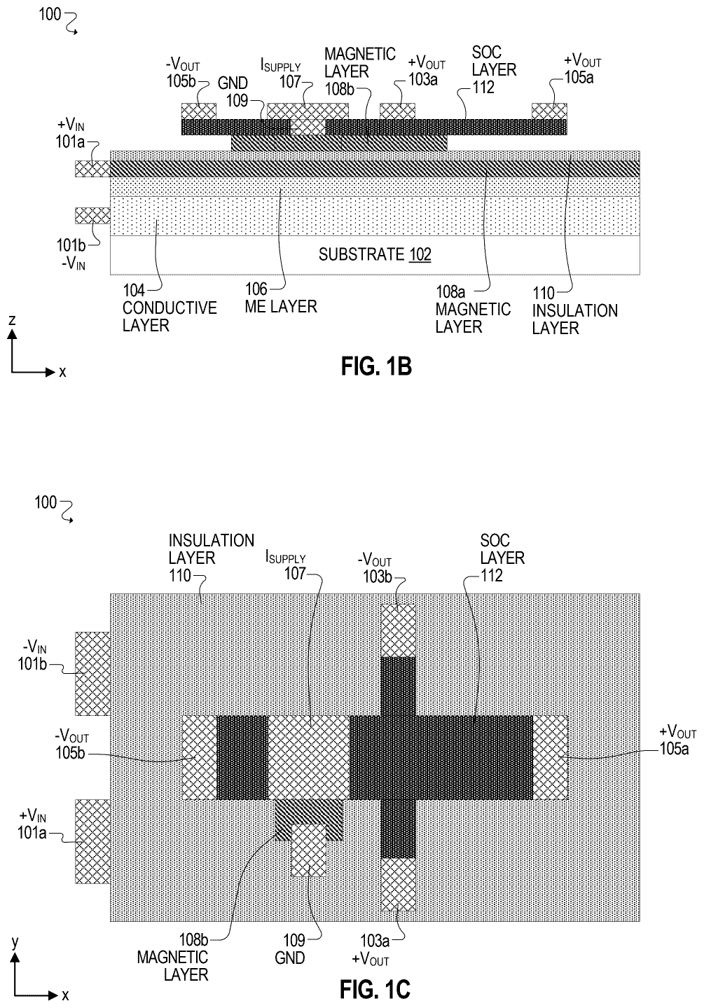

FIGS. 1A-C illustrate an example of a magnetoelectric spin-orbit (MESO) device 100 with conventional and unconventional spin-to-charge conversion. In the illustrated example, perspective (x-y-z), cross-section (x-z), and plan (x-y) views of MESO device 100 are shown in FIGS. 1A, 1B, and IC, respectively.

In the illustrated embodiment, MESO device 100 includes a compositionally-graded spin-orbit coupled (SOC) layer 112 with inversion asymmetry, which is made of a material with high spin-orbit coupling, such as platinum cobalt oxide (e.g., PtCoOₓ). When spin-polarized current is injected from the magnetic layers 108a-b (collectively, magnet 108) into the SOC layer 112, the spin-polarized current is converted into charge current due to both the inverse spin Hall effect (SHE) and the inverse Rashba effect, thus achieving both conventional and unconventional spin-to-charge conversion, which increases spin-to-charge conversion efficiency and enhances the output voltage (+−V_{OUT}) of MESO device 100.

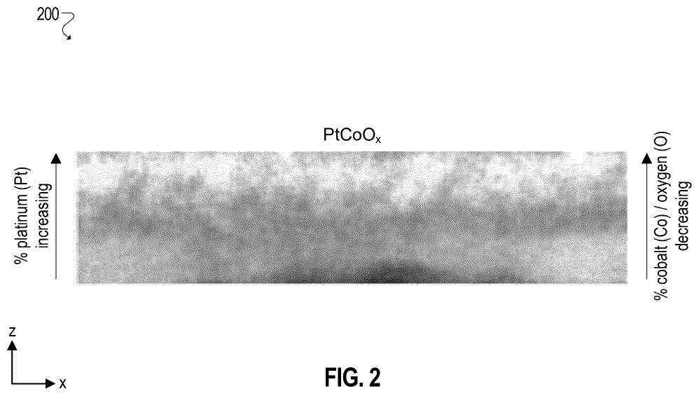

In particular, conventional spin-to-charge conversion is achieved in the SOC layer 112 due to the inverse SHE, which occurs in materials with high spin-orbit coupling, including heavy metals such as platinum (e.g., one of the elements in the SOC layer 112). Due to the inverse SHE, spin current (J_{S}) injected into the SOC layer 112 induces a traverse charge current (J_{C}), which flows perpendicular/orthogonal to both the direction of spin polarization (σ) and the flow of spin current (J_{S}). In the illustrated embodiment, for example, the direction of spin polarization (σ) is along the x axis, the flow of spin current (J_{S}) is along the z axis, and the flow of induced charge current (J_{C}) is along the y axis. In this manner, the induced charge current (J_{C}) flowing along the y axis produces an output voltage across differential output voltage contacts (+−V_{OUT}) 103a,b, which are positioned at the ends of the SOC layer 112 along the y axis. Separately, unconventional spin-to-charge conversion is achieved in the SOC layer 112 using the inverse Rashba effect, which occurs in materials with high spin-orbit coupling and structural inversion asymmetry. In particular, the platinum cobalt oxide material (e.g., PtCoOₓ) in the SOC layer 112 is compositionally graded using a vertical composition gradient, such that along the z axis of the SOC layer 112, the concentration of platinum (Pt) increases while the concentrations of cobalt (Co) and oxygen (O) decrease (e.g., as described further in connection with FIG. 2). Due to the vertical compositional gradient, the structural inversion symmetry of the SOC layer 112 breaks along the z axis, which results in inversion asymmetry along the z axis. Moreover, the resulting inversion asymmetry along the z axis, along with the high spin-orbit coupling of platinum cobalt oxide (e.g., PtCoOₓ), produces the inverse Rashba effect in the SOC layer 112, which results in unconventional spin-to-charge conversion. For example, due to the inverse Rashba effect, spin current (J_{S}) injected into the SOC layer 112 induces a traverse charge current (J_{C}), which flows in the direction of spin polarization (c) but perpendicular/orthogonal to the flow of spin current (J_{S}). In the illustrated embodiment, for example, the direction of spin polarization (c) and the flow of induced charged current (J_{C}) are both along the x axis, while the flow of spin current (J_{S}) is along the z axis. In this manner, the induced charge current (J_{C}) flowing along the x axis produces an output voltage across differential output voltage contacts (+−V_{OUT}) 105a,b, which are positioned at the ends of the SOC layer 112 along the x axis.

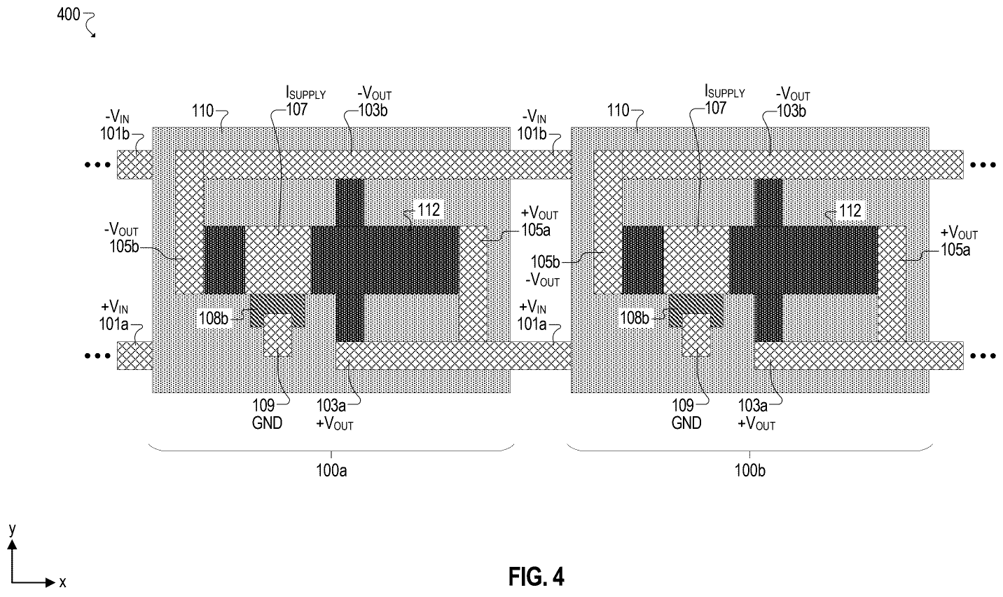

Unconventional spin-to-charge conversion is efficient in the platinum cobalt oxide material (e.g., PtCoOₓ) and increases the output voltage (+−V_{OUT}) significantly compared to conventional spin-to-charge conversion (e.g., up to 10×). However, the output voltage (+−V_{OUT}) is increased even further since conventional spin-to-charge conversion is also utilized, as the differential voltage outputs 103a-b, 105a-b of conventional and unconventional spin-to-charge conversion can be combined or added (e.g., as shown and described with respect to cascaded MESO logic 400 of FIG. 4).

The full operation of MESO device 100 will now be described in further detail. In the illustrated embodiment, MESO device 100 includes a substrate 102, a conductive layer 104, a magnetoelectric (ME) layer 106, magnetic layers 108a-b separated by an insulation layer 110 (collectively referred to as magnet 108), and a spin-orbit coupled (SOC) layer 112. MESO device 100 also includes electrical contacts (e.g., conductive contacts, electrodes, terminals, traces, interconnects) for differential voltage inputs (+−V_{IN}) 101a-b, differential voltage outputs (+−V_{OUT}) 103a-b, 105a-b, power supply (I_{SUPPLY}) 107, and ground (GND) 109.

The magnetic layers 108a-b and the intervening insulation layer 110 collectively function as a single magnet (e.g., when the direction of magnetization changes on one of the magnets 108a-b, it also changes on the other) and may collectively be referred to as magnet 108. Moreover, the magnetic layers 108a-b are made of a material that retains the magnetization setting induced on them, which means the magnet 108 is non-volatile. In some embodiments, for example, the magnetic layers 108a-b may be ferromagnetic (FM) layers made of a ferromagnetic (FM) material.

The differential input voltage (+−V_{IN}) controls the direction of magnetization induced on the magnet 108, while a supply voltage (V_{DD}) causes the direction of magnetization to be read out from the magnet 108 as a transverse differential output voltage (+−V_{OUT}). For example, when a differential input voltage (+−V_{IN}) is applied on the +−V_{IN} contacts 101a-b, the magnetoelectric (ME) layer 106 performs charge-to-spin conversion to convert electric charge current from the input voltage (+−V_{IN}) into a magnetic spin state (e.g., a particular direction of magnetization) in the magnet 108. When a supply voltage (V_{DD}) is applied on the I_{SUPPLY} contact 107, the SOC layer 112 performs spin-to-charge conversion to convert the magnetic spin state (e.g., the direction of magnetization) in the magnet 108 back into an electric charge current, which produces a transverse output voltage (+−V_{OUT}) on the +−V_{OUT} contacts 103a-b, 105a-b.

For example, in order to change the direction of magnetization on the magnet 108, a differential input voltage (+−V_{IN}) is applied on the +−V_{IN} contacts 101a-b, which causes charge current (I_{IN}) to flow from the +−V_{IN} contacts 101a-b, through the first magnetic layer 108a and conductive layer 104, respectively, and into the ME layer 106. The charge current (I_{IN}) ferroelectrically polarizes the ME layer 106, which causes the ME layer 106 to induce a particular direction of magnetization in the magnet 108.

In particular, the ME layer 106 is made from a magnetoelectric material that has both magnetic and electrical properties. Moreover, the ME layer 106 is configured as a magnetoelectric (ME) capacitor, with the conductive layer 104 and the magnet 108 serving as the electrical plates surrounding the ME capacitor layer 106. When charge current (I_{IN}) flows into the ME layer 106, the ferroelectric polarization of the ME layer 106 causes an electric field to form in the +−z direction depending on the polarity of the current (I_{IN}).

For example, when a positive differential input voltage (+−V_{IN}) is applied, the current flow is positive (e.g., in the +y direction) and an electric field forms in the −z direction in the ME layer 106. By contrast, when a negative differential input voltage (+−V_{IN}) is applied, the current flow is negative (e.g., in the −y direction) and an electric field forms in the +z direction in the ME layer 106.

As charge accumulates in the ME layer 106, the spin of electrons in the ME layer 106 become aligned at the interface with the ferromagnet 108 to form surface spin polarization, thus forming a magnetic field. The direction of magnetization (e.g., spin) of the magnetic field is defined by the direction of ferroelectric polarization in the ME layer 106. Further, as the magnetic field corresponding to the surface spin polarization is formed, it becomes exchange coupled with the ferromagnet 108, causing the magnetization in the ferromagnet 108 to align with the magnetic field of the surface spin polarization in the ME layer 106.

The direction of magnetization in the ferromagnet 108 is in plane (e.g., parallel to plane) in either the +−x direction, depending on the polarity of the input voltage (+−V_{IN}) and the corresponding ferroelectric polarization in the ME layer 106. In this manner, the direction of magnetization in the ferromagnet 108 can be controlled or switched by reversing the polarity of the input voltage (+−V_{IN}) (e.g., applying either positive or negative input voltage). Further, due to its ferromagnetic properties, the magnet 108 retains the induced direction of magnetization even after the input voltage (+−V_{IN}) is switched off (e.g., the magnet 108 is non-volatile).

In order to read out the direction of magnetization from the magnet 108, a supply voltage (V_{DD})) is applied on the power supply contact 107, which causes charge current (I_{SUPPLY}) to flow from the power supply contact 107 through the SOC layer 112 and into the magnet 108, which in turn causes the magnet 108 to produce spin polarized current whose spin polarization aligns with the direction of magnetization in the magnet 108. The spin polarized current in the magnet 108 is then injected into the SOC layer 112, which converts the spin polarized current into charge current due to the inverse spin Hall effect (SHE) and/or the inverse Rashba effect (e.g., as described above). For conventional spin-to-charge conversion, the resulting charge current in the SOC layer 112 flows in a perpendicular direction, which produces a transverse differential output voltage (+−V_{OUT}) on +−V_{OUT} contacts 103a-b. For unconventional spin-to-charge conversion, the resulting charge current in the SOC layer 112 flows in the direction of spin polarization, which produces a differential output voltage (+−V_{OUT}) on +−V_{OUT} contacts 105a-b. The polarity of the output voltage (+−V_{OUT}) indicates the direction of magnetization of the magnet 108, which serves as the output of the MESO device 100.

The substrate 102 may be made of any suitable substrate material(s), including, without limitation, dysprosium scandium oxide (DSO) (e.g., DyScO₃) or silicon (Si). For example, in some embodiments, the substrate 102 may be a DSO substrate, or a silicon substrate with an inserted templating layer. Thus, in some embodiments, the substrate 102 may be made of material(s) that include elements such as dysprosium (Dy), scandium (Sc), oxygen (O), and/or silicon (Si).

The electrical contacts (e.g., conductive contacts, electrodes, terminals, traces, interconnects) for +−V_{IN}, +−V_{OUT}, I_{SUPPLY}, and GND (101a-b, 103a-b, 105a-b, 107, 109) may be made of any suitable conductive material(s), including, without limitation, material(s) that include elements such as titanium (Ti), gold (Au), copper (Cu), silver (Ag), aluminum (Al), cobalt (Co), tungsten (W), tantalum (Ta), nickel (Ni), and/or graphene. For example, in some embodiments, the electrical contacts may be made of one or more materials that include titanium (Ti) and gold (Au).

The conductive layer 104 may be made of any suitable conductive material(s), including, without limitation, strontium ruthenium oxide (SrRuO (SRO)). Thus, in some embodiments, the conductive layer 104 may be made of material(s) that include elements such as strontium (Sr), ruthenium (Ru), and/or oxygen (O).

The ME layer 106 may be made of any suitable magnetoelectric and/or multiferroic material(s), including, but not limited to: (i) multiferroics such as bismuth ferrite (BFO) (e.g., BiFeO₃), lanthanum doped bismuth ferrite (LBFO) (e.g., LaBiFeO₃), samarium doped bismuth ferrite (e.g., SmBiFeO₃), lutetium ferrite (LFO) (e.g., LuFeO₂, LuFeO₃, LuFc₂O₄), TbMnO₃, and other multiferroic oxides; (ii) magnetostrictive materials such as Fe₃Ga, TbₓDy₁₋ₓFe₂, FeRh; (iii) electrically tuned exchange-mediated magnetoelectrics such as Cr₂O₃ and Fe₂TeO₆; and/or (iv) any other suitable materials with magnetoelectric properties, such as BiTiO₃, lead zirconate titanate (PZT), lead magnesium niobate-lead titanate (PMN-PT), and aluminum nitride (AlN). Thus, in some embodiments, the ME layer 106 may be made of material(s) that include elements such as bismuth (Bi), iron (Fe), oxygen (O), lanthanum (La), samarium (Sm), lutetium (Lu), terbium (Tb), manganese (Mn), gallium (Ga), dysprosium (Dy), rhodium (Rh), chromium (Cr), tellurium (Te), aluminum (Al), nitrogen (N), titanium (Ti), magnesium (Mg), zirconium (Zr), niobium (Nb), and/or lead (Pb).

The magnetic layers 108a-b may be made of any suitable magnetic or ferromagnetic material(s), including, without limitation, cobalt iron (CoFc), nickel iron (NiFc), LaSrMnO₃, and/or Co-doped or Fe-doped perovskite oxide (e.g., CaTiO₃). Thus, in some embodiments, the magnetic layers 108a-b may be made of material(s) that include elements such as cobalt (Co), iron (Fc), nickel (Ni), gadolinium (Gd), lanthanum (La), strontium (Sr), manganese (Mn), oxygen (O), calcium (Ca), and/or titanium (Ti).

The magnet insulation layer 110 may be made of any suitable insulating/insulator or dielectric material(s), including, without limitation, magnesium oxide (MgO), aluminum oxide (AlO) (e.g., Al₂O₃), titanium oxide (TiO) (e.g., TiO₃), silicon oxide (SiO) (e.g., SiO₂), silicon nitride (SiN) (e.g., Si₃N₄), and/or hafnium oxide (HfO) (e.g., HfO₂). Thus, in some embodiments, the magnet insulation layer 110 may be made of material(s) that include elements such as magnesium (Mg), aluminum (Al), titanium (Ti), hafnium (Hf), silicon (Si), oxygen (O), and/or nitrogen (N).

The SOC layer 112 may be made of any suitable material(s) with relatively high spin-orbit coupling, referred to herein as SOC materials. SOC materials may include materials and elements with a relatively high SOC coefficient and/or relatively high atomic number (as spin-orbit coupling is directly proportional to atomic number), including, without limitation, platinum cobalt oxide (PtCoOₓ), heavy metals, topological insulators, and/or two-dimensional (2D) semiconductor materials. Examples of heavy metals that may be used in the SOC layer 112 include, without limitation, platinum (Pt), tantalum (Ta), and/or tungsten (W). Examples of topological insulators that may be used in the SOC layer 112 include, without limitation, bismuth selenide (BiSe), bismuth antimony telluride (BiSbTe), antimony telluride (SbTe), and/or bismuth antimonide (BiSb). Examples of 2D semiconductor materials that may be used in the SOC layer 112 include, without limitation, transition-metal dichalcogenides (TMD) (e.g., TMD monolayers) and/or graphene (e.g., graphene monolayers). A TMD may refer to an atomically thin semiconductor of the type MX₂, where M is a transition-metal atom (e.g., tungsten (W)) and X is a chalcogen atom (e.g., selenium (Se), sulfur(S)), and one layer of M atoms is sandwiched between two layers of X atoms. Graphene may refer to an allotrope of carbon (C) with a single layer of atoms. Thus, in some embodiments, the SOC layer 112 may be made of material(s) that include elements such as platinum (Pt), tantalum (Ta), tungsten (W), cobalt (Co), oxygen (O), bismuth (Bi), selenium (Se), antimony (Sb), tellurium (Te), sulfur(S), and/or carbon (C). In some embodiments, the SOC layer 112 may have a thickness of approximately 8 nanometers (nm).

Further, in various embodiments, MESO device 100 may be implemented using other types, numbers, and/or arrangements of layers and materials than those shown and described with respect to FIG. 1. For example, certain components of MESO device 100 may be added, replaced, omitted, and/or rearranged. Some embodiments may include both conventional and unconventional spin-to-charge conversion, while others may include one or the other. Throughout this disclosure, a layer may refer to one or more layers of material, such as a single layer of material, or a stack of layers.

FIG. 2 illustrates an example of the composition of a spin-orbit coupled (SOC) layer 200 for a MESO device. In the illustrated example, the SOC layer 200 is shown from a cross-section view across the x-z plane. In some embodiments, the SOC layer 200 may be used to implement SOC layer 112 of MESO device 100.

In the illustrated example, the SOC layer 200 is a compositionally-graded layer with high spin-orbit coupling and inversion asymmetry. In particular, the SOC layer 200 is made of a material that includes platinum (Pt), cobalt (Co), and oxygen (O), such as platinum cobalt oxide (e.g., PtCoOₓ), which has high spin-orbit coupling. Moreover, the SOC layer 200 is compositionally graded using a vertical composition gradient, which breaks inversion symmetry along the z axis. In particular, along the z axis of SOC layer 200, the concentration (%) of platinum (Pt) increases while the concentrations (%) of cobalt (Co) and oxygen (O) decrease. This change in composition breaks the structural inversion symmetry of SOC layer 200 along the z axis, and the resulting inversion asymmetry leads to unconventional spin-to-charge conversion in the SOC layer 200 due to the Rashba effect.

In particular, the Rashba effect occurs due to the spin-orbit coupling in materials with structural inversion asymmetry (e.g., where structural inversion symmetry is broken), which results in spin splitting of electronic bands in momentum space. The Rashba effect enables manipulation and control of electron spins using electric fields, which can be leveraged for charge-to-spin conversion (Rashba effect) and spin-to-charge conversion (inverse Rashba effect) in spintronic devices.

In the illustrated example, the inverse Rashba effect occurs in SOC layer 200 due to the high/strong spin-orbit coupling of platinum cobalt oxide (PtCoOₓ) and the inversion asymmetry from the compositional gradient, which results in unconventional spin-to-charge conversion in the SOC layer 200.

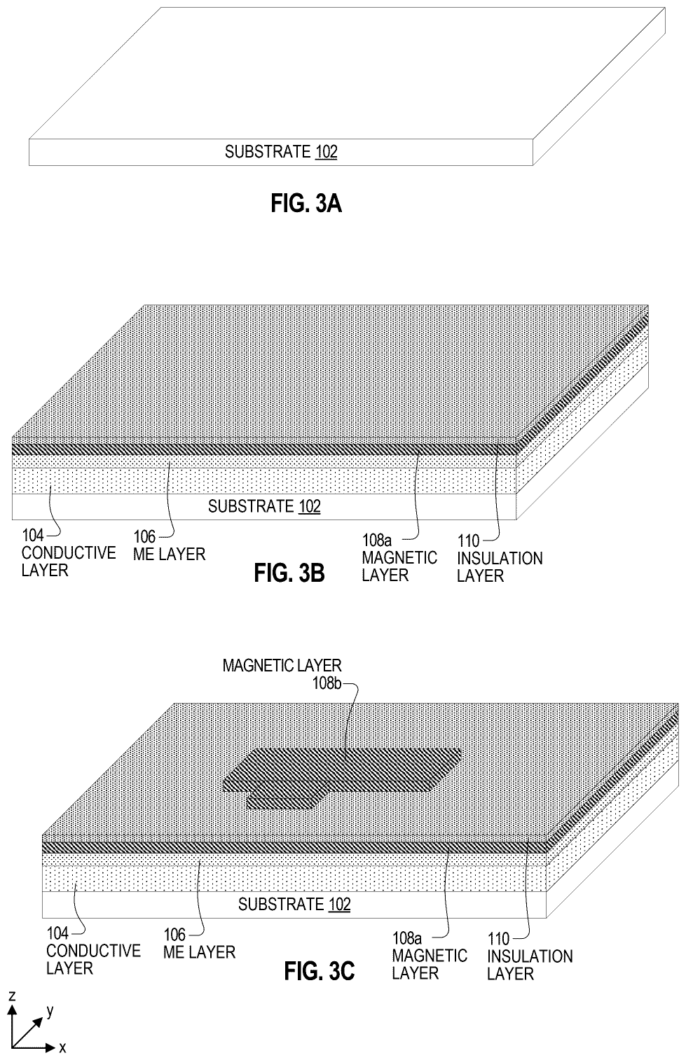

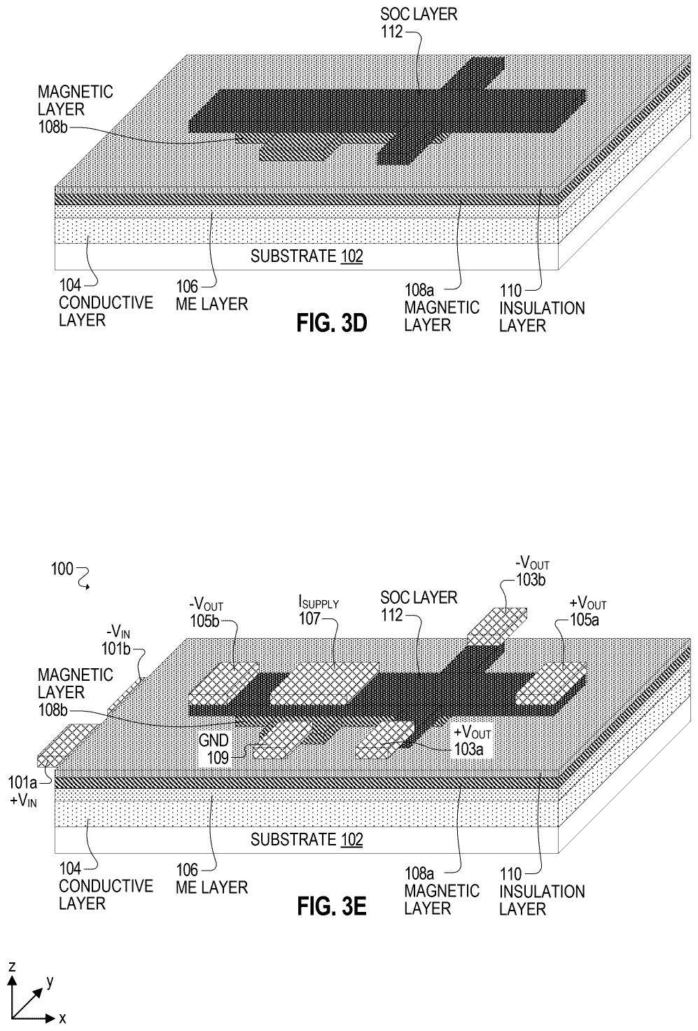

FIGS. 3A-E illustrate an example process flow for forming a MESO device 100 with conventional and unconventional spin-to-charge conversion. In the illustrated example, the process flow is used to form MESO device 100 of FIG. 1. It will be appreciated in light of the present disclosure that the illustrated process flow is only one example methodology for arriving at MESO device 100.

In FIG. 3A, a substrate 102 is received. In some embodiments, the substrate 102 may be made of a material that includes dysprosium scandium oxide (DSO) (e.g., DyScO₃) or silicon (Si).

In FIG. 3B, a stack of layers is formed over the substrate 102, including a conductive layer 104, a magnetoelectric (ME) layer 106, a first magnetic layer 108a, and an insulation layer 110. The conductive layer 104 is over the substrate 102, the ME layer 106 is over the conductive layer 104, the first magnetic layer 108a is over the ME layer 106, and the insulation layer 110 is over the first magnetic layer 108a.

In FIG. 3C, a second magnetic layer 108b is formed over the insulation layer 110, and portions of the second magnetic layer 108b are etched to form the requisite pattern for that layer.

In FIG. 3D, a spin-orbit coupling (SOC) layer 112 is formed over the second magnetic layer 108b, and portions of the SOC layer 112 are etched to form the requisite pattern for that layer. In particular, the SOC layer 112 includes a first portion extending along the x direction, and a second portion extending along the y direction substantially perpendicular to the first portion.

In FIG. 3E, electrical contacts (e.g., conductive contacts, electrodes, terminals, traces, interconnects) are formed for differential voltage inputs (+−V_{IN}) 101a-b, different voltage outputs (+−V_{OUT}) 103a-b, 105a-b, power supply (I_{SUPPLY}) 107, and ground (GND) 109. For example, the differential voltage input (+−V_{IN}) contacts 101a-b are formed on the first magnetic layer 108a and the conductive layer 104, respectively. The different voltage output (+−V_{OUT}) contacts 103a-b for conventional spin-to-charge conversion are formed on the respective ends of the SOC layer 112 along the y axis (e.g., the perpendicular extensions), and the different voltage output (+−V_{OUT}) contacts 105a-b for unconventional spin-to-charge conversion are formed on the respective ends of the SOC layer 112 along the x axis. The power supply (I_{SUPPLY}) contact 107 is formed over the SOC layer 112, and the ground (GND) contact 109 is formed over the second magnetic layer 108b.

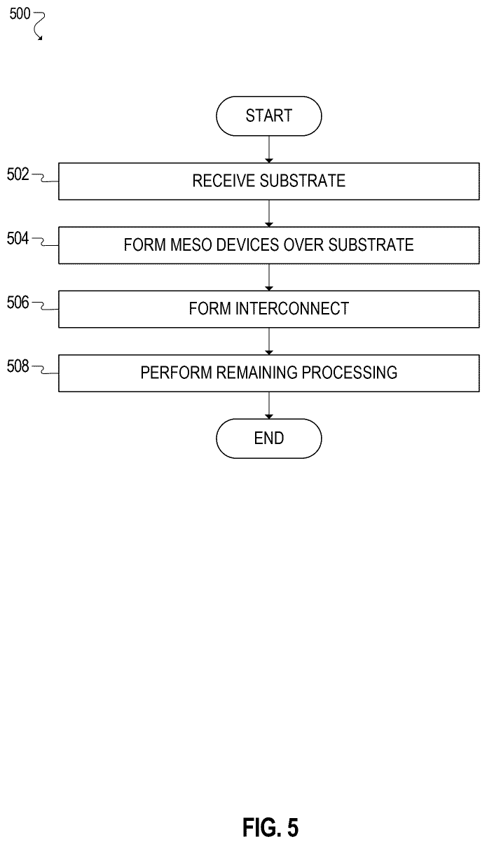

At this point, the MESO device 100 may be complete. In some embodiments, however, additional processing may be performed, as described below with respect to the process flow of FIG. 5.

FIG. 4 illustrates an example of cascaded MESO logic 400. In the illustrated embodiment, the cascaded MESO logic 400 includes multiple cascaded MESO devices 100a-b shown from a top-down/plan view (e.g., the x-y plane), which are respectively implemented using the design of MESO device 100 from FIG. 1. Moreover, MESO devices 100a-b are cascaded, such that the differential voltage outputs 103a-b, 105a-b (+−Vₒᵤₜ) of MESO device 100a are coupled to the differential voltage inputs 101a-b (+−Vᵢₙ) of MESO device 100b.

In particular, the positive differential voltage outputs 103a, 105a (+Vₒᵤₜ) of MESO device 100a are coupled to the positive differential voltage input 101a (+Vᵢₙ) of MESO device 100b, and the negative differential voltage outputs 103b, 105b (−Vₒᵤₜ) of MESO device 100a are coupled to the negative differential voltage input 101b (−Vᵢₙ) of MESO device 100b. Thus, the positive and negative differential voltage outputs 103a-b, 105a-b (+−Vₒᵤₜ) of MESO device 100a, respectively, are added together and fed into the positive and negative differential voltage inputs 101a-b (+−Vᵢₙ) of MESO device 100b, respectively. In this manner, the output of MESO device 100a drives the input of MESO device 100b.

In actual embodiments, any number of MESO logic devices may be cascaded using any desired arrangement. For example, the differential voltage outputs (+−V_{OUT}) of each MESO device may be coupled to the differential voltage inputs (+−V_{IN}) of one or more MESO devices, and vice versa.

FIG. 5 illustrates a flowchart 500 for forming integrated circuitry with MESO devices in accordance with certain embodiments. It will be appreciated in light of the present disclosure that the illustrated process flow is only one example methodology for arriving at the example MESO devices shown and described throughout this disclosure (e.g., MESO device 100, cascaded MESO logic 400). The steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The illustrated process flow may be used to form one or more IC dies (e.g., semiconductor devices) that respectively include MESO devices with an interconnect (e.g., for signaling and power delivery). In some embodiments, the MESO devices and interconnect may collectively implement logic circuitry in the respective IC dies.

The flowchart begins at block 502 by receiving a substrate. In some embodiments, the substrate may be a dysprosium scandium oxide (DSO) substrate, or a silicon substrate with a templating layer. Moreover, the substrate may be a wafer-level or panel-level substrate for wafer or panel process flows.

The flowchart then proceeds to block 504 to form a layer of MESO devices over the substrate. In some embodiments, the layer of MESO devices may be formed using the process flow of FIGS. 3A-E. For example, a stack of layers may be formed over the substrate (e.g., as shown in FIGS. 3B-C), including a conductive/electrical layer, a magnetoelectric (ME) layer, a first magnetic layer, a magnet insulation layer, and a second magnetic layer. The second magnetic layer is etched into the requisite pattern for that layer (e.g., as shown in FIG. 3C). A spin-orbit coupled (SOC) layer is formed over the second magnetic layer and etched into the requisite pattern for that layer (e.g., as shown in FIG. 3D). Further, electrical contacts (e.g., conductive contacts, electrodes, terminals, traces, interconnects) are formed for the respective MESO devices, including for the differential voltage inputs (e.g., +−V_{IN}), the different voltage outputs (e.g., +−V_{OUT}), power supply (e.g., I_{SUPPLY}), and ground (e.g., GND) (e.g., as shown in FIG. 3E).

The flowchart then proceeds to block 506 to form an interconnect for the MESO devices. For example, the interconnect may provide the requisite connections (e.g., conductive traces) to and from the input (e.g., +−V_{IN}), output (e.g., +−V_{OUT}), power supply (e.g., I_{SUPPLY}), and ground (e.g., GND) contacts on the respective MESO devices.

In some embodiments, metallization/interconnect patterning processes may be used to form traces and vias for the interconnect. For example, multiple conductive (e.g., metal) layers may be formed over the MESO device layer, along with intervening dielectric layers separating the conductive layers. The conductive layers, which may also be referred to as metal layers, may be made of one or more electrically-conductive materials that include one or more metals (e.g., any of the metals/alloys described throughout this disclosure). Further, the dielectric layers may include one or more dielectric materials (e.g., any of the dielectric materials described throughout this disclosure). Moreover, conductive traces may be patterned (e.g., etched) in the conductive layers, and vias may be formed between conductive layers (e.g., through the intervening dielectric layers) to electrically couple traces in different conductive layers. The conductive traces and vias patterned in and between the conductive layers may collectively form the interconnect for the MESO devices.

The flowchart then proceeds to block 508 to perform any remaining processing, such as inter-layer dielectric (ILD) filling, planarization, interconnect bump formation, backside processing (e.g., for backside power delivery), etc. In wafer or panel process flows, the completed wafer or panel may be diced to singulate the IC dies on the wafer or panel. The singulated IC dies may then be incorporated into an IC package, circuit board, electronic device or system (e.g., electronic device 900), etc.

The singulated IC dies may include a variety of components and circuitry, including, without limitation, processing circuitry, communication circuitry, memory circuitry, and/or storage circuitry. In some embodiments, for example, the IC die(s) may include a central processing unit (CPU), graphics processing unit (GPU), vision processing unit (VPU), microprocessor, microcontroller, field-programmable gate array (FPGA), application-specific integrated circuit (ASIC), input/output (I/O) controller, network interface controller (NIC), memory, and/or solid-state storage, among other examples.

At this point, the flowchart may be complete. In some embodiments, however, the flowchart may restart and/or certain blocks may be repeated. For example, in some embodiments, the flowchart may restart at block 502 to continue forming integrated circuitry with MESO devices with the same or similar design.

### Example Integrated Circuit Embodiments

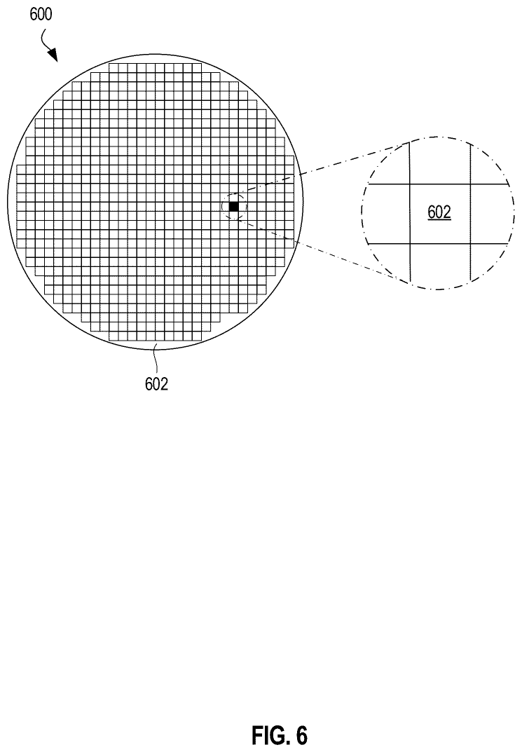

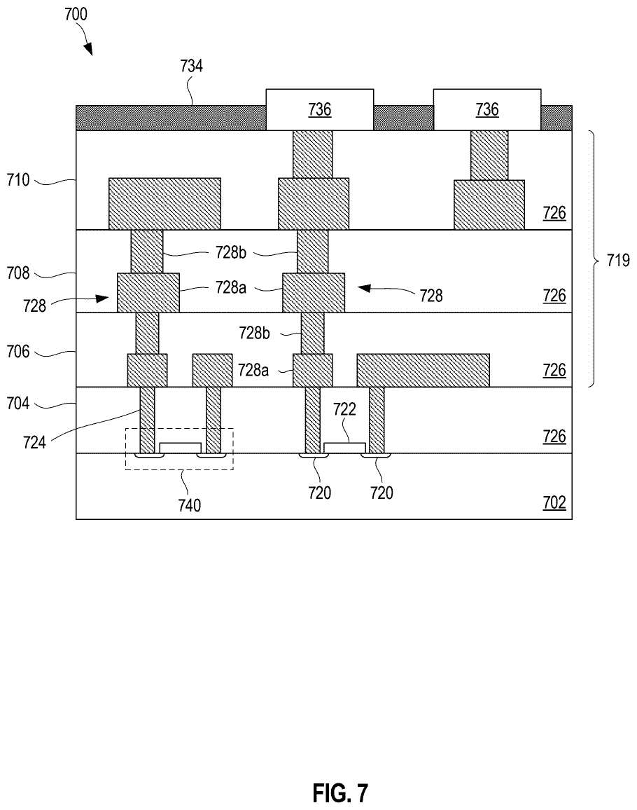

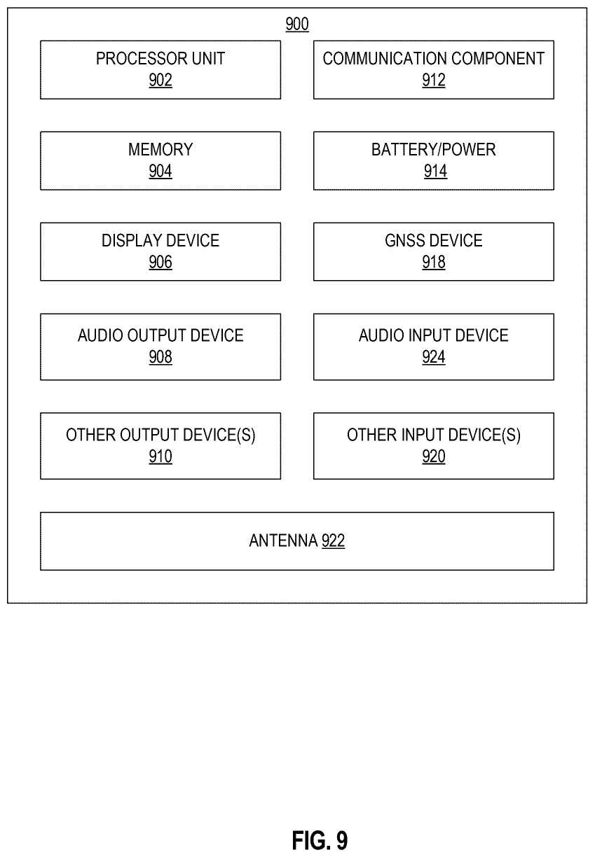

FIG. 6 is a top view of a wafer 600 and dies 602 that may be included in, or may include, any of the embodiments disclosed herein. In some embodiments, for example, the dies 602 may include one or more MESO devices (e.g., MESO device 100). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

FIG. 7 is a cross-sectional side view of an integrated circuit device 700 that may be included in any of the embodiments disclosed herein (e.g., in any of the dies). One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as any of the conductive contacts described throughout this disclosure.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as any of the conductive contacts described throughout this disclosure.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. These additional conductive contacts may serve as any of the conductive contacts described throughout this disclosure. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

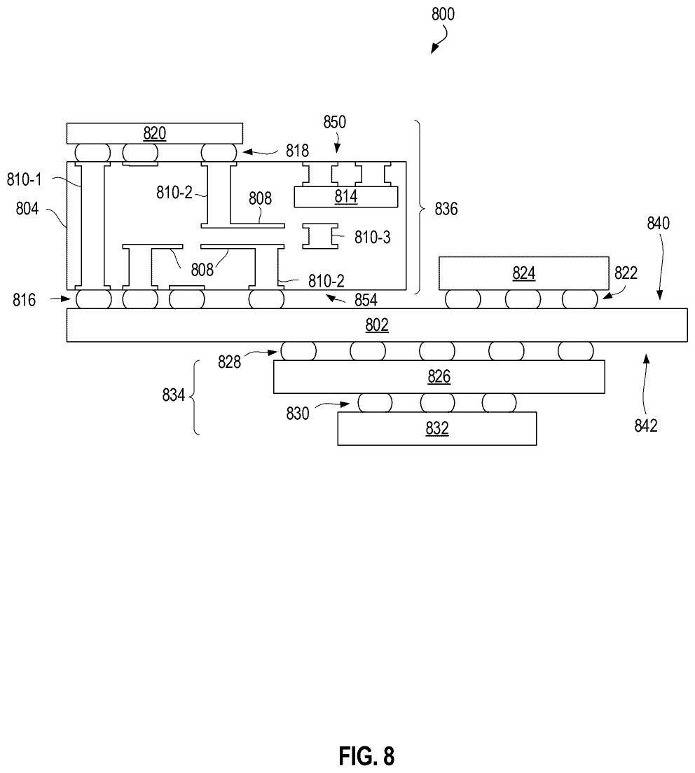

FIG. 8 is a cross-sectional side view of an integrated circuit device assembly 800 that may include any of the embodiments disclosed herein. In some embodiments, for example, the embedded devices 814 and/or IC components 820, 824, 826, 832 of the integrated circuit device assembly 800 may include one or more MESO devices (e.g., MESO device 100). In some embodiments, the integrated circuit device assembly 800 may be a microelectronic assembly. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may take the form of any suitable ones of the embodiments of the microelectronic assemblies disclosed herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 816 may serve as the coupling components illustrated or described for any of the substrate assembly or substrate assembly components described herein, as appropriate.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more of the embodiments disclosed herein. For example, the electrical device 900 and/or its respective components (e.g., communication components 912, processor units 902, memory 904) may include one or more MESO devices (e.g., MESO device 100), integrated circuit device assemblies 800, integrated circuit components 820, integrated circuit devices 700, or integrated circuit dies 602 disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include other output device(s) 910 (or corresponding interface circuitry, as discussed above). Examples of the other output device(s) 910 may include an audio codec, a video codec, a printer, a wired or wireless transmitter for providing information to other devices, or an additional storage device.

The electrical device 900 may include other input device(s) 920 (or corresponding interface circuitry, as discussed above). Examples of the other input device(s) 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for case of understanding and may vary by some margin of error in actual embodiments (e.g., due to fabrication processes, etc.).

The terms “substantially,” “close,” “approximately,” “near,” and “about” may refer to being within +/−10% of a target value unless otherwise specified.

Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

In some embodiments, the phrase “A is located on B” or the phrase “A is adjacent to B” means that at least a part of A is in direct physical contact or indirect physical contact (having one or more other features between A and B) with at least a part of B. Moreover, the phrase “B is between A and C” means that at least part of B is in or along a space separating A and C and that the at least part of B is in direct or indirect physical contact with A and C.

The terms “coupled” and “connected” may refer to either a direct or indirect connection, such as a direct electrical, mechanical, or magnetic connection, or an indirect connection through one or more passive or active intermediary elements, components, or devices.

The phrases “in an embodiment,” “according to some embodiments,” “in accordance with embodiments,” “in embodiments,” and the like may each refer to one or more of the same or different embodiments.

The terms “comprises,” “comprising,” “includes,” “including,” “having” and the like specify the presence of the stated elements (e.g., features, components, materials, steps, operations) but do not preclude the presence or addition of one or more other elements.

The phrase “and/or” as used herein refers to and encompasses any and all possible combinations of one or more of the associated listed items.

The singular forms “a,” “an,” and “the” are intended to include the plural forms as well, unless the context clearly indicates otherwise. For example, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

For purposes of some embodiments, the transistors in various circuits and logic blocks described herein may be metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BICMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.). Moreover, in some embodiments, spintronic logic devices (e.g., magnetoelectric spin-orbit (MESO) logic devices) may be used in addition to, or as an alternative to, MOS transistors.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

In the foregoing description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure.

It is to be appreciated that the layers and materials described above are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted above may be fabricated on underlying lower level back end of line (BEOL) interconnect layers.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

The disclosed embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combination thereof.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a semiconductor device, comprising: a first layer comprising a conductive material; a second layer over the first layer, wherein the second layer comprises a magnetoelectric material; one or more third layers over the second layer, wherein the one or more third layers comprise one or more ferromagnetic materials; and a fourth layer over the one or more third layers, wherein the fourth layer comprises platinum, cobalt, and oxygen.

Example 2 includes the semiconductor device of Example 1, wherein the one or more third layers are a plurality of third layers, wherein the plurality of third layers include: a first ferromagnetic layer, wherein the first ferromagnetic layer comprises a ferromagnetic material; a second ferromagnetic layer, wherein the second ferromagnetic layer comprises a ferromagnetic material; and an insulation layer between the first and second ferromagnetic layers.

Example 3 includes the semiconductor device of Example 2, wherein the insulation layer comprises magnesium and oxygen.

Example 4 includes the semiconductor device of Example 2, wherein the fourth layer includes a first portion and a second portion, wherein the second portion is substantially perpendicular to the first portion.

Example 5 includes the semiconductor device of Example 4, further comprising: a first conductive trace coupled to the first layer; a second conductive trace coupled to the first ferromagnetic layer; a third conductive trace coupled to a first end of the first portion of the fourth layer; a fourth conductive trace coupled to a second end of the first portion of the fourth layer; a fifth conductive trace coupled to a first end of the second portion of the fourth layer; a sixth conductive trace coupled to a second end of the second portion of the fourth layer; a seventh conductive trace coupled to the fourth layer, wherein the seventh conductive trace is further coupled to a power supply; and an eighth conductive trace coupled to the second ferromagnetic layer, wherein the eighth conductive trace is further coupled to ground.

Example 6 includes the semiconductor device of Example 1, wherein the fourth layer is compositionally graded, and wherein the fourth layer has inversion asymmetry based on a composition gradient of the fourth layer.

Example 7 includes the semiconductor device of Example 6, wherein the fourth layer has varying concentrations of platinum, cobalt, and oxygen across a particular dimension, wherein a concentration of platinum in the fourth layer increases across the particular dimension, and wherein concentrations of cobalt and oxygen in the fourth layer decrease across the particular dimension.

Example 8 includes the semiconductor device of Example 1, wherein the fourth layer is polycrystalline.

Example 9 includes the semiconductor device of Example 1, wherein the fourth layer has a thickness of approximately 8 nanometers or less.

Example 10 includes the semiconductor device of Example 1, wherein the magnetoelectric material comprises: bismuth, iron, and oxygen; lanthanum, bismuth, iron, and oxygen; lutetium, iron, and oxygen; or terbium, manganese, and oxygen.

Example 11 includes the semiconductor device of Example 1, wherein the conductive material comprises strontium, ruthenium, and oxygen.

Example 12 includes the semiconductor device of Example 1, wherein the one or more ferromagnetic materials comprise cobalt and iron.

Example 13 includes the semiconductor device of Example 1, further comprising a magnetoelectric spin-orbit (MESO) device, wherein the MESO device comprises the first layer, the second layer, the one or more third layers, and the fourth layer.

Example 14 includes an electronic device, comprising: a substrate; and one or more magnetoelectric spin-orbit (MESO) devices over the substrate, wherein individual MESO devices comprise: a conductive layer; a magnetoelectric layer over the conductive layer; a first ferromagnetic layer over the magnetoelectric layer; a second ferromagnetic layer over the first ferromagnetic layer; and a spin-orbit coupling (SOC) layer over the second ferromagnetic layer, wherein the SOC layer comprises platinum, cobalt, and oxygen.

Example 15 includes the electronic device of Example 14, wherein the SOC layer includes a first portion and a second portion, wherein the second portion is substantially perpendicular to the first portion.

Example 16 includes the electronic device of Example 15, further comprising: a first conductive trace coupled to the conductive layer; a second conductive trace coupled to the first ferromagnetic layer; a third conductive trace coupled to a first end of the first portion of the SOC layer; a fourth conductive trace coupled to a second end of the first portion of the SOC layer; a fifth conductive trace coupled to a first end of the second portion of the SOC layer; a sixth conductive trace coupled to a second end of the second portion of the SOC layer; a seventh conductive trace coupled to the SOC layer, wherein the seventh conductive trace is further coupled to a power supply; and an eighth conductive trace coupled to the second ferromagnetic layer, wherein the eighth conductive trace is further coupled to ground.

Example 17 includes the electronic device of Example 14, wherein the SOC layer is compositionally graded, and wherein the SOC layer has inversion asymmetry based on a composition gradient of the SOC layer.

Example 18 includes the electronic device of Example 17, wherein the SOC layer has varying concentrations of platinum, cobalt, and oxygen across a particular dimension, wherein a concentration of platinum in the SOC layer increases across the particular dimension, and wherein concentrations of cobalt and oxygen in the SOC layer decrease across the particular dimension.

Example 19 includes the electronic device of Example 14, wherein the SOC layer is polycrystalline.

Example 20 includes the electronic device of Example 14, wherein the SOC layer has a thickness of approximately 8 nanometers or less.

Example 21 includes the electronic device of Example 14, further comprising an insulation layer between the first and second ferromagnetic layers.

Example 22 includes the electronic device of Example 21, wherein the insulation layer comprises magnesium and oxygen.

Example 23 includes the electronic device of Example 14, wherein: the magnetoelectric layer comprises bismuth, iron, and oxygen; the conductive layer comprises strontium, ruthenium, and oxygen; or at least one of the first ferromagnetic layer or the second ferromagnetic layer comprises cobalt and iron.

Example 24 includes the electronic device of Example 14, further comprising an integrated circuit, wherein the integrated circuit comprises processing circuitry, memory circuitry, storage circuitry, or communication circuitry, wherein one or more of the MESO devices are comprised in the processing circuitry, the memory circuitry, the storage circuitry, or the communication circuitry.

Example 25 includes a system, comprising: a printed circuit board; and one or more integrated circuits coupled to the printed circuit board, wherein at least one of the integrated circuits comprises one or more magnetoelectric spin-orbit (MESO) devices, wherein individual MESO devices comprise: a conductive layer; a magnetoelectric layer over the conductive layer; a first ferromagnetic layer over the magnetoelectric layer; an insulation layer over the first ferromagnetic layer; a second ferromagnetic layer over the insulation layer; and a polycrystalline layer over the second ferromagnetic layer, wherein the polycrystalline layer comprises platinum, cobalt, and oxygen.

Example 26 includes the system of Example 25, wherein the one or more integrated circuits include one or more of a processor, a memory, an input/output (I/O) controller, or a network interface controller.

Example 27 includes a method, comprising: receiving a substrate; forming a first layer over the substrate, wherein the first layer comprises a conductive material; forming a second layer over the first layer, wherein the second layer comprises a magnetoelectric material; forming one or more third layers over the second layer, wherein the one or more third layers comprise one or more ferromagnetic materials; and forming a fourth layer over the one or more third layers, wherein the fourth layer comprises platinum, cobalt, and oxygen.

Example 28 includes the method of Example 27, wherein forming the one or more third layers over the second layer comprises: forming a first ferromagnetic layer over the second layer; forming an insulation layer over the first ferromagnetic layer; and forming a second ferromagnetic layer over the insulation layer.

1. A semiconductor device, comprising:
a first layer comprising a conductive material;
a second layer over the first layer, wherein the second layer comprises a magnetoelectric material;
one or more third layers over the second layer, wherein the one or more third layers comprise one or more ferromagnetic materials; and
a fourth layer over the one or more third layers, wherein the fourth layer comprises platinum, cobalt, and oxygen.

2. The semiconductor device of claim 1, wherein the one or more third layers are a plurality of third layers, wherein the plurality of third layers include:
a first ferromagnetic layer, wherein the first ferromagnetic layer comprises a ferromagnetic material;
a second ferromagnetic layer, wherein the second ferromagnetic layer comprises a ferromagnetic material; and
an insulation layer between the first and second ferromagnetic layers.

3. The semiconductor device of claim 2, wherein the insulation layer comprises magnesium and oxygen.

4. The semiconductor device of claim 2, wherein the fourth layer includes a first portion and a second portion, wherein the second portion is substantially perpendicular to the first portion.

5. The semiconductor device of claim 4, further comprising:
a first conductive trace coupled to the first layer;
a second conductive trace coupled to the first ferromagnetic layer;
a third conductive trace coupled to a first end of the first portion of the fourth layer;
a fourth conductive trace coupled to a second end of the first portion of the fourth layer;
a fifth conductive trace coupled to a first end of the second portion of the fourth layer;
a sixth conductive trace coupled to a second end of the second portion of the fourth layer;
a seventh conductive trace coupled to the fourth layer, wherein the seventh conductive trace is further coupled to a power supply; and
an eighth conductive trace coupled to the second ferromagnetic layer, wherein the eighth conductive trace is further coupled to ground.

6. The semiconductor device of claim 1, wherein the fourth layer is compositionally graded, and wherein the fourth layer has inversion asymmetry based on a composition gradient of the fourth layer.

7. The semiconductor device of claim 1, wherein the fourth layer is polycrystalline.

8. The semiconductor device of claim 1, wherein the magnetoelectric material comprises:
bismuth, iron, and oxygen;
lanthanum, bismuth, iron, and oxygen;
lutetium, iron, and oxygen; or
terbium, manganese, and oxygen.

9. The semiconductor device of claim 1, wherein the conductive material comprises strontium, ruthenium, and oxygen.

10. The semiconductor device of claim 1, wherein the one or more ferromagnetic materials comprise cobalt and iron.

11. The semiconductor device of claim 1, further comprising a magnetoelectric spin-orbit (MESO) device, wherein the MESO device comprises the first layer, the second layer, the one or more third layers, and the fourth layer.

12. An electronic device, comprising:
a substrate; and
one or more magnetoelectric spin-orbit (MESO) devices over the substrate, wherein individual MESO devices comprise:
a conductive layer;
a magnetoelectric layer over the conductive layer;
a first ferromagnetic layer over the magnetoelectric layer;
a second ferromagnetic layer over the first ferromagnetic layer; and
a spin-orbit coupling (SOC) layer over the second ferromagnetic layer, wherein the SOC layer comprises platinum, cobalt, and oxygen.

13. The electronic device of claim 12, wherein the SOC layer includes a first portion and a second portion, wherein the second portion is substantially perpendicular to the first portion.

14. The electronic device of claim 12, wherein the SOC layer has varying concentrations of platinum, cobalt, and oxygen across a particular dimension, wherein a concentration of platinum in the SOC layer increases across the particular dimension, and wherein concentrations of cobalt and oxygen in the SOC layer decrease across the particular dimension.

15. The electronic device of claim 12, wherein the SOC layer is polycrystalline.

16. The electronic device of claim 12, further comprising an insulation layer between the first and second ferromagnetic layers.

17. The electronic device of claim 12, wherein:
the magnetoelectric layer comprises bismuth, iron, and oxygen;
the conductive layer comprises strontium, ruthenium, and oxygen; or
at least one of the first ferromagnetic layer or the second ferromagnetic layer comprises cobalt and iron.

18. The electronic device of claim 12, further comprising an integrated circuit, wherein the integrated circuit comprises processing circuitry, memory circuitry, storage circuitry, or communication circuitry, wherein one or more of the MESO devices are comprised in the processing circuitry, the memory circuitry, the storage circuitry, or the communication circuitry.

19. A system, comprising:
a printed circuit board; and
one or more integrated circuits coupled to the printed circuit board, wherein at least one of the integrated circuits comprises one or more magnetoelectric spin-orbit (MESO) devices, wherein individual MESO devices comprise:
a conductive layer;
a magnetoelectric layer over the conductive layer;
a first ferromagnetic layer over the magnetoelectric layer;
an insulation layer over the first ferromagnetic layer;
a second ferromagnetic layer over the insulation layer; and
a polycrystalline layer over the second ferromagnetic layer, wherein the polycrystalline layer comprises platinum, cobalt, and oxygen.

20. The system of claim 19, wherein the one or more integrated circuits include one or more of a processor, a memory, an input/output (I/O) controller, or a network interface controller.
